(19) United States
(12) Patent Application Publication
(10) Pub. No.: US 2010/0168889 A1
(43) Pub. Date: Jul. 1, 2010

(54) SUBSTRATE TREATMENT APPARATUS, SUBSTRATE TREATMENT METHOD AND STORAGE MEDIUM

(75) Inventors: Koichi SEKIDO, Nirasaki-shi (JP); Koji Maekawa, Nirasaki-shi (JP); Kunio Takano, Nirasaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Tokyo (JP)

(21) Appl. No.: 12/651,718

(22) Filed: Jan. 4, 2010

Related U.S. Application Data
(63) Continuation of application No. PCT/JP08/61639, filed on Jun. 26, 2008.

(30) Foreign Application Priority Data
Jul. 3, 2007 (JP) 2007-175606

(51) Int. Cl. H01L 21/683; G06F 17/50; G06F 17/00

(52) U.S. Cl. 700/97; 700/112; 700/121; 700/114

(57) ABSTRACT

A substrate treatment apparatus eliminates breakage of a wafer W due to having the wafer supported by a supporting member when heat treatment is performed on the wafer W a plurality of times by a heat treatment module. The substrate processing apparatus includes a recipe setting unit for setting process conditions for a process recipe for the semiconductor wafer W and a direction of the semiconductor wafer W, by associating the conditions and the direction with each other. Through the recipe setting unit, the direction of the semiconductor wafer W can be set, and the semiconductor wafer W can be arranged in a direction set by an alignment module. Thus, portions R to be supported by the supporting members 60a, 60b and 60c on the rear surface of the semiconductor wafer can be changed every time the heat treatment module performs heat treatment.

This application is a Continuation Application of PCT International Application No. PCT/JP2008/061639 filed on Jun. 26, 2008, which designated the United States.

### FIELD OF THE INVENTION

The present invention relates to a technique for performing heat treatment on a semiconductor wafer (hereinafter, referred to as a “wafer”) after a direction of the wafer is aligned in an alignment module.

### BACKGROUND OF THE INVENTION

In a semiconductor manufacturing process, a semiconductor manufacturing apparatus, called a multi-chamber system, including a plurality of processing modules for performing vacuum processes on wafers one by one is used. The semiconductor manufacturing apparatus generally includes a loading unit of a wafer carrier, an atmospheric transfer chamber connected to the loading unit, a vacuum transfer chamber connected to the atmospheric transfer chamber through a load-lock chamber, and a plurality of processing modules connected to the vacuum transfer chamber. The semiconductor manufacturing apparatus is appropriate when a series of processes is performed on the wafer with a high throughput, for example, when a vacuum annealing process is performed after a plasma process.

Further, in the multi-chamber system, a notch or an orientation flat formed at a peripheral portion of a wafer is required to be always arranged in the same direction (at the same position) before the wafer is loaded into each module of the chamber in order to accurately evaluate a processing state of the surface of the wafer in a plasma process, an annealing process or the like. Accordingly, in the semiconductor manufacturing apparatus, for example, the atmospheric transfer chamber is provided with an alignment module for aligning the direction of the wafer and a position of the center of the wafer. In the alignment module, a parameter associated with the direction of the wafer is set as a fixed value in advance by a maker because the parameter is not involved in the process. Accordingly, the parameter associated with the direction of the wafer is not included in setting items for a process procedure (process recipe) of the wafer to be processed in a chamber.

Further, when the multi-chamber system includes a heat treatment module and a plasma processing module as described above, the heat treatment module is used to anneal the wafer in order to recover the damage generated on the surface of the wafer in the plasma process (see, e.g., claim 1, paragraphs 0029 and 0030 of Japanese Patent Laid-open Publication No. 2006-156995 and corresponding U.S. Patent Application Publication No. 2008/0000551). In the heat treatment module, the wafer is supported by three supporting pins. Further, as described above, since the wafer transferred into the vacuum transfer chamber is maintained in the same direction, the wafer transferred into the heat treatment module is supported by the supporting pins while the wafer is arranged in the same direction.

Further, the wafer unloaded from the multi-chamber system may be returned to the system and annealed in the heat treatment module depending on the type of semiconductor devices or a wafer inspection operation.

In the annealing process, the wafer is heated while being supported by the wafer supporting pins. In this case, heat applied to the wafer dissipates from the wafer via the supporting pins. Accordingly, portions of the wafer in contact with the supporting pins undergo a local reduction in temperature and Si crystal defects (e.g., slip) may occur at the corresponding portions. If the annealing process is performed once, the slip generated in this case has little influence on yield. However, when the annealing process is performed twice, since the direction of the wafer transferred to the heat treatment module is not changed and the same portions of the rear surface of the wafer are supported by the supporting pins in the first and second annealing processes, thermal stress is applied to the same portions in the first and second annealing processes, thereby causing slip or worsening the slip generated in the first annealing process. Consequently, it leads to a reduction in production yield.

### SUMMARY OF THE INVENTION

The present invention has been devised in order to solve the problems described above. It is an object of the present invention to provide a substrate treatment apparatus, a substrate treatment method and a storage medium capable of preventing damage to a wafer due to being supported by supporting members when heat treatment is performed on the wafer a plurality of times in a heat treatment module.

In accordance with a first aspect of the present invention, there is provided a substrate treatment apparatus comprising: a heat treatment module for performing heat treatment on a semiconductor wafer locally supported from a rear surface thereof by a supporting member provided in the heat treatment module; a recipe setting unit configured to set process conditions of a process recipe of the semiconductor wafer and a direction of the semiconductor wafer by associating the conditions and the direction with each other; an alignment module connected to the recipe setting unit to align the semiconductor wafer in the direction set by the recipe setting unit; a loading port on which a carrier accommodating semiconductor wafers is loaded; and a transfer unit for transferring a semiconductor wafer unloaded from the carrier loaded on the loading port to the alignment module, wherein the transfer unit unloads the semiconductor wafer from the alignment module to transfer the semiconductor wafer to the heat treatment module.

In the substrate treatment apparatus, the recipe setting unit may have a recipe setting screen serving as an input unit through which the process conditions such as a transfer path of the wafer are set and a display unit on which setting contents are displayed. The recipe setting screen may include a supplementary information section allowing input and display of supplementary information of the process recipe in addition to the process conditions, and the direction of the semiconductor wafer can be inputted through the supplementary information section.

Further, in the substrate treatment apparatus, the loading port may be connected to a transfer chamber, and the transfer chamber may be connected to the heat treatment module and a plasma processing module.

In accordance with a second aspect of the present invention, there is provided a substrate treatment method comprising the steps of: (a) unloading a semiconductor wafer from a carrier loaded on a loading port and transferring the semiconductor wafer to an alignment module; (b) aligning a direction of the semiconductor wafer at a first angle in the alignment module; (c) loading the semiconductor wafer into the heat treatment module and performing heat treatment on the semiconductor wafer locally supported from a rear surface thereof by supporting members; (d) aligning the direction of the semiconductor wafer at a second angle different from the first angle in the alignment module; and (e) loading the semiconductor wafer into the same module as the heat treatment module and performing heat treatment on the semiconductor wafer locally supported from a rear surface thereof by supporting members.

In the substrate treatment method, the semiconductor wafer may be transferred from the alignment module to the heat treatment module through a transfer chamber. The substrate treatment method may further comprise performing a plasma process on the semiconductor wafer in a plasma processing module connected to the transfer chamber between the steps (b) and (d).

Further, the substrate treatment method may further comprise, between the steps (c) and (d), (c1) unloading the semiconductor wafer from the loading port; and (c2) loading the semiconductor wafer accommodated in the carrier on the loading port again. Further, the substrate treatment method may further comprise setting in advance the direction of the semiconductor wafer to be aligned by the alignment module by using a recipe setting unit between the steps (c1) and (c2).

In accordance with a third aspect of the present invention, there is provided a storage medium storing a program which is executed by a controller controlling a substrate treatment apparatus, including an alignment module for performing an alignment on a semiconductor wafer and a heat treatment module for performing heat treatment on the aligned semiconductor wafer, to perform a substrate treatment method including the steps of: (a) unloading a semiconductor wafer from a carrier loaded on a loading port and transferring the semiconductor wafer to an alignment module; (b) aligning a direction of the semiconductor wafer at a first angle in the alignment module; (c) loading the semiconductor wafer into the heat treatment module and performing heat treatment on the semiconductor wafer locally supported from a rear surface thereof by supporting members; (d) aligning the direction of the semiconductor wafer at a second angle different from the first angle in the alignment module; and (e) loading the semiconductor wafer into the same module as the heat treatment module and performing heat treatment on the semiconductor wafer locally supported from a rear surface thereof by supporting members.

In accordance with the aspects of the present invention, in the alignment module, the semiconductor wafer can be arranged in the direction set by the recipe setting unit. Accordingly, the portion of the rear surface of the semiconductor wafer supported by the supporting member can be changed whenever the heat treatment is performed in the heat treatment module. As described above, stress due to a difference in temperatures of the portion supported by the supporting member and the other portion can be prevented from being repeatedly applied to the same portion of the semiconductor wafer. Thus, wafer slip can be prevented or minimized, thereby preventing a reduction in production yield.

### BRIEF DESCRIPTION OF THE DRAWINGS

The objects and features of the present invention will become apparent from the following description of embodiments, given in conjunction with the accompanying drawings, in which:

FIG. 1 is a transversal cross sectional view showing a semiconductor manufacturing apparatus in accordance with an embodiment of the present invention;

FIG. 2 is a longitudinal cross sectional view of an example of an alignment module used in the semiconductor manufacturing apparatus of FIG. 1;

FIG. 3 is a longitudinal cross sectional view of an example of a heat treatment module used in the semiconductor manufacturing apparatus of FIG. 1;

FIG. 4 is a perspective view schematically showing a mounting table in the heat treatment module of FIG. 3;

FIG. 5 illustrates a block diagram showing a controller provided in the semiconductor manufacturing apparatus of FIG. 1;

FIG. 6 illustrates a recipe setting screen of a recipe setting screen provided in the controller of FIG. 5;

FIG. 7 is a diagram for explaining a reference direction of a notch;

FIG. 8 is a diagram for explaining an operation of the semiconductor manufacturing apparatus of FIG. 1;

FIG. 9 is a diagram for explaining the operation of the semiconductor manufacturing apparatus of FIG. 1;

FIG. 10A is a diagram for explaining a relationship between positions of supporting pins and a direction of the notch in a first annealing process; and

FIG. 10B is a diagram for explaining a relationship between positions of supporting pins and a direction of the notch in a second annealing process.

### DETAILED DESCRIPTION OF THE EMBODIMENTS

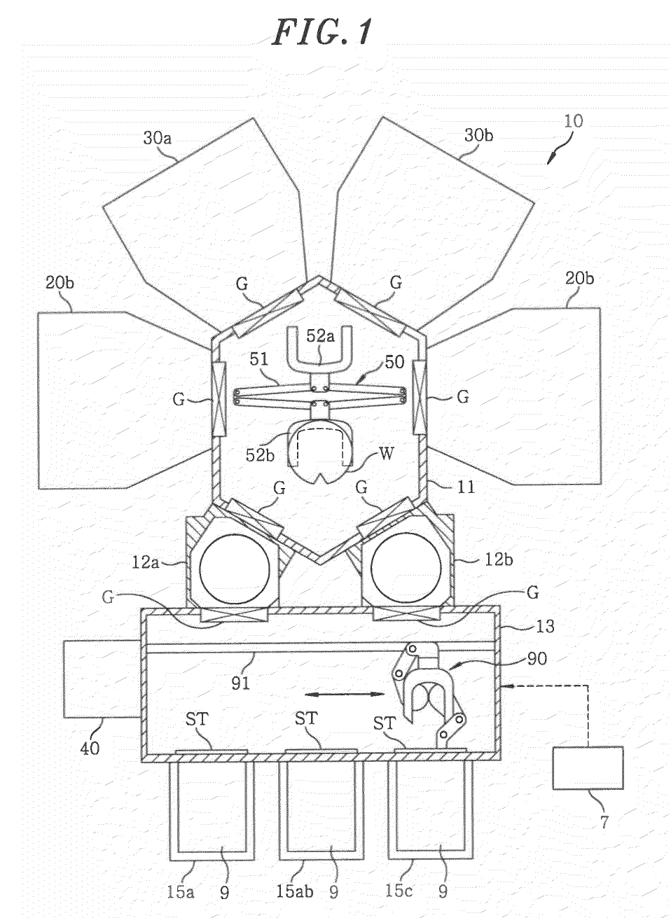

Hereinafter, an embodiment of the present invention will be described. FIG. 1 is a transversal cross sectional view showing an example of a semiconductor manufacturing apparatus that is a substrate treatment apparatus in accordance with the embodiment of the present invention. In FIG. 1, reference numeral 10 designates a single-wafer semiconductor manufacturing apparatus in which semiconductor wafers (hereinafter, referred to as “wafers”) W are transferred one by one and a predetermined process is performed on each wafer. The semiconductor manufacturing apparatus 10 includes, e.g., two plasma processing modules 20a and 20b and two heat treatment modules 30a and 30b. The plasma processing modules 20a and 20b and the heat treatment modules 30a and 30b are airtightly connected to four sides of a vacuum transfer chamber 11 having a hexagonal transversal cross section, respectively. Further, one of the plasma processing modules 20a and 20b and one of the heat treatment modules 30a and 30b may be provided and other processing modules may be added to the semiconductor manufacturing apparatus 10.

Load-lock chambers 12a and 12b are airtightly connected to two sides of the vacuum transfer chamber 11, respectively. An atmospheric transfer chamber 13 having a horizontally long box shape is connected to the load-lock chambers 12a and 12b to be opposite to the vacuum transfer chamber 11. Loading ports 15a, 15b and 15c are provided at the side of the atmospheric transfer chamber 13 to be opposite to the load-lock chambers 12a and 12b. The loading ports 15a, 15b and 15c may be mounted with three FOUPs (carriers) 9, each one capable of receiving a plurality of, e.g., twenty-five, wafers W. Further, in FIG. 1, reference number G indicates a gate valve.

That is, the vacuum transfer chamber 11, the load-lock chambers 12a and 12b and the atmospheric transfer chamber 13 form a transfer chamber connected to the loading ports 15a, 15b and 15c. The plasma processing modules 20a and 20b and the heat treatment modules 30a and 30b are connected to the transfer chamber.

The vacuum transfer chamber 11 includes a transfer arm unit 50 that is a transfer unit for loading/unloading wafers W into/from the plasma processing modules 20a and 20b, the heat treatment modules 30a and 30b and the load-lock chambers 12a and 12b. The transfer arm unit 50 is disposed at an approximately central portion of the vacuum transfer chamber 11. The transfer arm unit 50 has two fork-shaped arms 52a and 52b, each one supporting a lower peripheral portion of the wafer W at a leading end of a rotatable and extensible/contractible portion 51. The two arms 52a and 52b are attached to the rotatable and extensible/contractible portion 51 to be directed in opposite directions.

Shutters ST are respectively provided at the three loading ports 15a, 15b and 15c of the atmospheric transfer chamber 13 on which the FOUPs 9 are mounted. When the FOUPs 9 containing wafers W are mounted on the loading port 15a, 15b and 15c, the shutters ST are opened such that the atmospheric transfer chamber 13 can communicate with the FOUPs 9 while outside air is prevented from entering the atmospheric transfer chamber 13. In other words, the loading port 15a, 15b and 15c are directly connected to the transfer chamber through the shutters ST.

Further, the atmospheric transfer chamber 13 includes a transfer arm unit 90 that is a transfer unit for loading/unloading wafers W into/from the FOUPs 9 and the load-lock chambers 12a and 12b. The transfer arm unit 90 has a multi-joint arm structure and is movable on a rail 91 in an arrangement direction of the FOUPs 9. Further, an alignment module 40 is provided at the side of the atmospheric transfer chamber 13 to correct a direction (position in a rotational direction) of the wafer W and a position of the center of the wafer W.

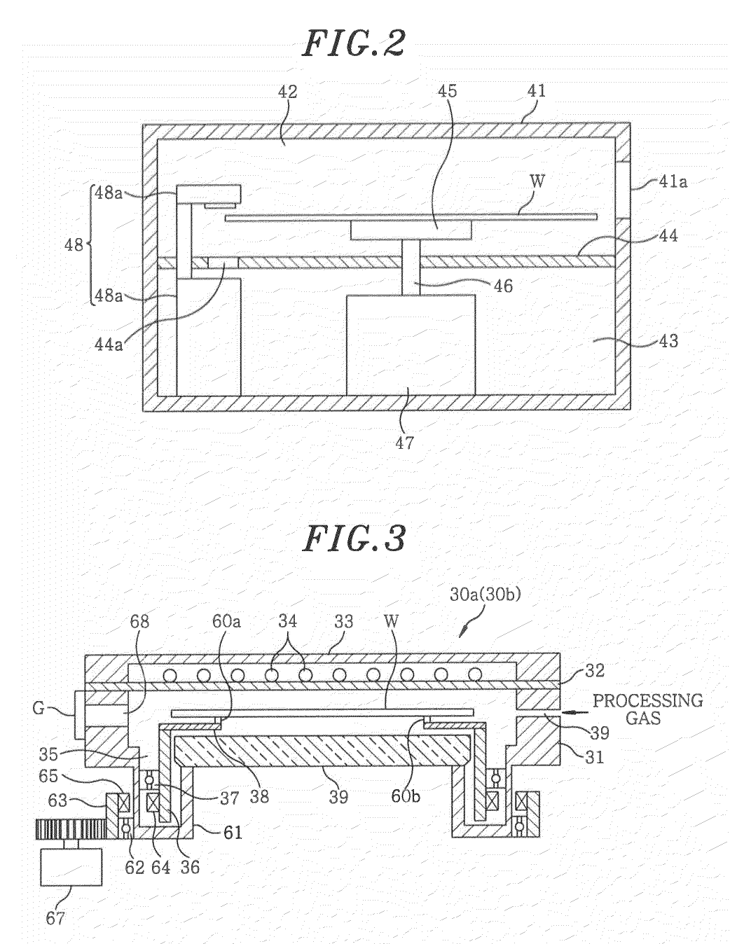

As shown in FIG. 2, the alignment module 40 has an approximately box-shaped and flat container 41. The container 41 is attached to a sidewall of the atmospheric transfer chamber 13. As shown in FIG. 2, the container 41 includes an upper room 42 and a lower room 43 separated by a partition plate 44. A loading/unloading port 41a is provided at a sidewall of the upper room 42, so that a wafer W can be transferred between the container 41 and the atmospheric transfer chamber 13 through the loading/unloading port 41a by using the transfer arm unit 90. A mounting table 45 is disposed in the upper room 42 to mount a wafer W thereon. The mounting table 45 is connected to a rotation driving mechanism 47 provided in the lower room 43 via a shaft 46. The mounting table 45 is driven by the rotation driving mechanism 47 so that the mounting table can be rotated around an axial line parallel to a vertical axis.

A detector 48 is provided in the container 41 to detect a peripheral position of the wafer W mounted on the mounting table 45. The detector 48 has a light emitting part 48b disposed in the lower room 43 and formed of, e.g., LEDs and a light receiving part 48a disposed in the upper room 42 and formed of, e.g., a CCD sensor. Light emitted from the light emitting part 48b is incident on the light receiving part 48a through a hole 44a formed in the partition plate 44.

The light receiving part 48a is configured to output a signal (detection data) representing an amount of the incident light to a controller 7 to be described later. Further, the controller 7 calculates a position of a notch formed at a peripheral portion of the wafer W based on variation in the amount of light incident on the light receiving part 48a while the wafer W is rotated by about one revolution by the rotation driving mechanism 47. Moreover, the controller 7 rotates the mounting table 45 such that the notch is oriented in a reference direction and, then, rotates the mounting table 45 based on a notch angle inputted in a supplementary information section 84, as will be described later.

Further, the alignment module 40 calculates a center position of the wafer W based on the detection data of the peripheral portion of the wafer W, and acquires a misalignment amount of the wafer W relative to a rotation center of the mounting table 45. A receiving position of the transfer arm unit 90 at which the wafer W is loaded is corrected based on the misalignment amount such that the wafer W is loaded at a specific position of the transfer arm unit 90.

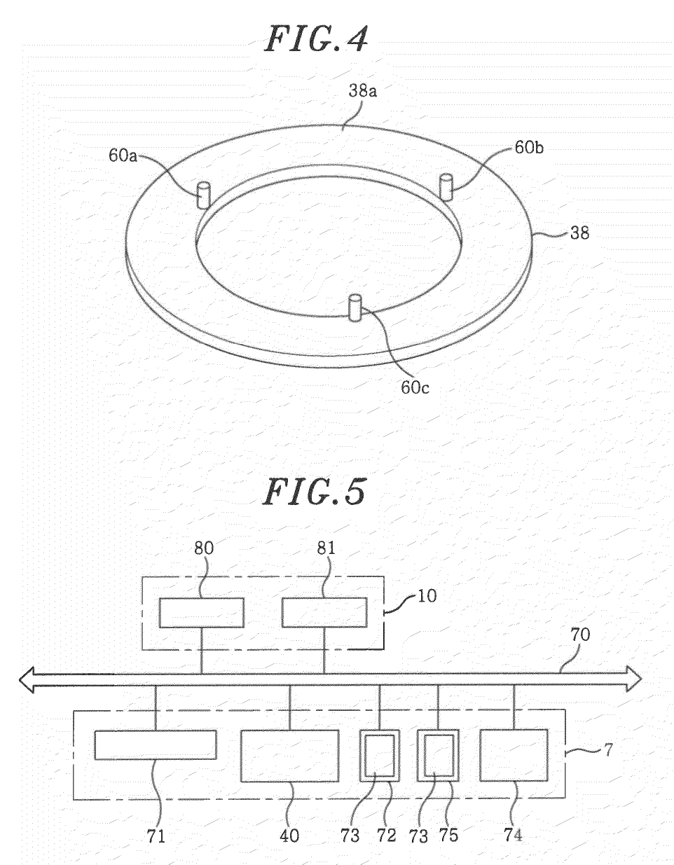

Next, the heat treatment modules 30a and 30b will be described with reference to FIGS. 3 and 4. Although various heat treatment modules may be employed, the heat treatment modules 30a and 30b using lamp annealing are explained as an example in this embodiment. Each of the heat treatment modules 30a and 30b includes a transparent quartz glass plate 32 expanded horizontally in an upper inner portion of a processing chamber 31. A heating source, e.g., a lamp 34, is arranged in a space between a cover 33 and the quartz glass plate 32. The lamp 34 is operated by power supplied from a power supply (not shown) to heat the wafer W in the processing chamber 31 to a predetermined temperature.

An annular groove 35 is formed at a peripheral side of a bottom portion of the processing chamber 31. An inner rotational body 36 is provided in the groove 35. The inner rotational body 36 is supported by an inner wall of the groove 35 via a bearing 37. The inner rotational body 36 is rotatable around an axial line parallel to a vertical axis. A ring-shaped mounting table 38 is provided at an upper end portion of the inner rotational body 36. As shown in FIG. 4, supporting members 60a, 60b and 60c that are locally in contact with a bottom peripheral portion of the wafer W to support the wafer W are provided at a surface part 38a of the mounting table 38. In the illustrated example, the supporting members 60a, 60b and 60c are configured as three pins. The three pins 60a, 60b and 60c are arranged on the same circumference at specific intervals. The mounting table 38 is rotated integrally with the inner rotational body 36.

A bottom central portion of the processing chamber 31 is configured as a glass plate 39. The glass plate 39 is connected to a housing 61 forming the groove 35. An outer rotational body 63 is supported on the outside of the housing 61 via a bearing 62. The outer rotational body 63 is rotatable around an axial line parallel to a vertical axis. The inner rotational body 36 and the outer rotational body 63 are respectively provided with magnetic poles 64 and 65 forming a magnetic coupling.

The outer rotational body 63 is rotated by driving a stepping motor 67. Further, when the outer rotational body 63 is rotated, the inner rotational body 36 is rotated together with the outer rotational body 63 by a magnetic force. A gas exhaust port (not shown) is formed at a sidewall of the processing chamber 31. A gas in the processing chamber 31 is exhausted through the gas exhaust port by using a vacuum exhaust unit, so that a specific vacuum atmosphere can be maintained in the processing chamber 31. An opening 68 through which the wafer W is loaded and unloaded is formed at the sidewall of the processing chamber 31. A gate valve G is provided to cover the opening 68. A gas supply port 69 is provided below the quartz glass plate 32 at the sidewall of the processing chamber 31. A nitrogen gas and an oxygen gas serving as processing gases are supplied into the processing chamber 31 through the gas supply port 69.

The semiconductor manufacturing apparatus 10 further includes a controller 7. The controller 7 will be described with reference to FIG. 5. In FIG. 5, reference numeral 70 designates a bus. The bus 70 is connected to a signal line for transmitting control signals to a processing system 80 including the heat treatment modules 30a and 30b and a transfer system 81 including the transfer arm unit 50 in the semiconductor manufacturing apparatus 10. Further, the bus 70 is connected to a recipe setting unit 71, the alignment module 40, a CPU 74, a storage medium 72, a storage unit 75 and the like. The storage medium 72 and/or the storage unit 75 may store a processing program 73 and a recipe therein. FIG. 5 illustrates a block diagram functionally showing the above-described components.

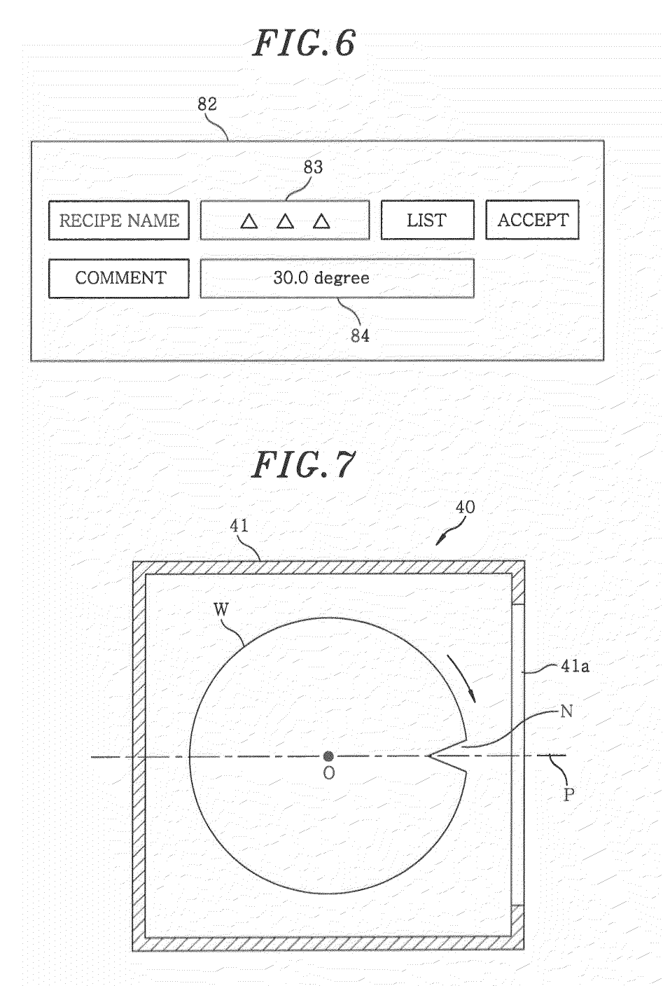

The recipe setting unit 71 includes a recipe setting screen (interface for setting a recipe) 82 for setting process conditions of a process recipe of the wafer W, e.g., a process pressure, a process temperature, gas flow rates, processing time and a transfer path of the wafer W. As shown in FIG. 6, the recipe setting screen 82 is formed of a touch panel including a softswitch and the like. As shown in FIG. 6, a recipe name section 83 and a supplementary information section 84 are provided on the recipe setting screen 82. The recipe name section 83 describes a formal number of a selected recipe, and the supplementary information section 84 describes supplementary information, e.g., contents and purposes of the recipe and the like. Further, the supplementary information section 84 has a function of receiving an input angle to set a direction of the wafer W supported to have a horizontal surface, specifically, a direction of the notch formed on the wafer W.

When a notch angle ranging, e.g., from 0 to 360 degrees is inputted through the supplementary information section 84, the alignment module 40 controls rotation and standstill of the wafer W such that the notch aligned in the reference direction is rotated by the input angle. For example, the reference direction is oriented from a rotation center of a rotation stage to a center of the loading/unloading port 41a as shown in FIG. 7. FIG. 7 also describes a reference line P defining the reference direction. That is, in this embodiment, the direction of the wafer W is determined by a rotation angle of the notch of the wafer W, i.e., an angle by which the horizontally-arranged wafer W is rotated around a rotation axis that passes the center of the wafer and is perpendicular to the surface of the wafer W from a position on the reference line P.

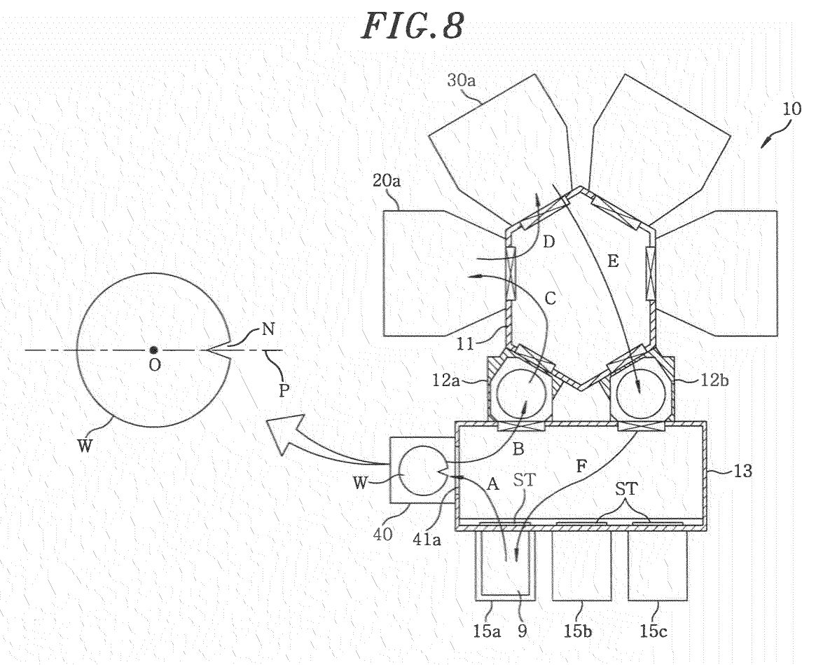

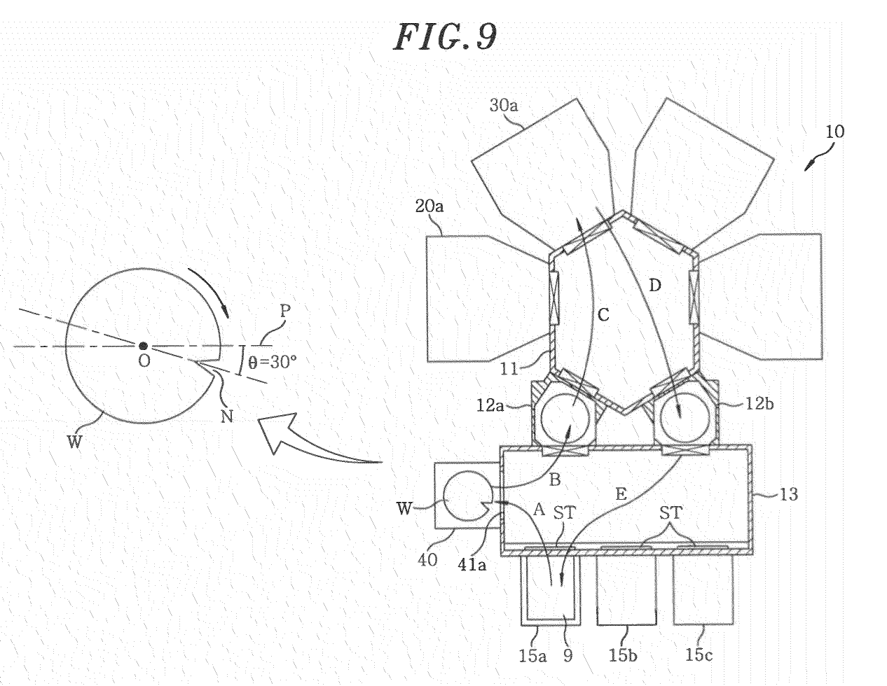

As described above, the alignment module 40 has a function of calculating a position of the notch formed at the peripheral portion of the wafer W based on the detection data transmitted from the light receiving part 48a. The processing program 73 is designed to execute groups of steps corresponding procedures shown in FIGS. 8 and 9. The processing program 73 is stored in the storage medium 72. The storage medium 72 may be a memory such as a ROM and RAM, a hard disk, a disc-shaped storage medium such as a CD-ROM, or the like. In case of using the fixed storage medium 72 such as a hard disk, the processing program 73 may be transmitted from another apparatus via, e.g., a dedicated line and the processing program 73 may be installed online on the storage medium 72. The controller 7 may directly execute the processing program 73 stored in the storage medium 72, or may execute the processing program 73 after the processing program 73 is transferred to the storage unit 75 included in the controller 7.

Next, the operation of the semiconductor manufacturing apparatus 10 will be described with reference to FIGS. 8 and 9. First, the FOUP 9 serving as a wafer carrier accommodating wafers W is loaded (mounted) on the loading port 15a from the outside. Then, an operator sets a process recipe through the recipe setting screen 82. Such setting is executed by selecting a recipe from a group of recipes stored in, e.g., the storage medium 72 or the storage unit 75 of the controller 7. A plasma process and an annealing process are continuously performed in the semiconductor manufacturing apparatus 10. Further, the wafer W arranged in a predetermined direction is required to be loaded into the plasma processing module 20a (20b) in which the mounting table is fixed. Accordingly, the alignment module 40 sets the direction of the wafer W in advance.

In this embodiment, the direction of the wafer W to be arranged by the alignment module 40 is the reference direction, i.e., an angle of zero degrees. Accordingly, “zero degrees” may be inputted to the supplementary information section 84 of the recipe setting screen 82. Even though there is no input, an angle of zero degrees is automatically set. That is, the supplementary information section 84 is used in case of setting a specific direction of the wafer W. If an angle is not inputted to the supplementary information section 84, the semiconductor manufacturing apparatus 10 automatically sets an angle of zero degrees.

When the setting of the recipe is completed, the shutter ST of the loading port 15a is opened and an unprocessed wafer W is transferred into the atmospheric transfer chamber 13 from the FOUP 9 loaded on the loading port 15a by the transfer arm unit 90. The wafer W unloaded from the FOUP 9 is transferred to the alignment module 40 through the atmospheric transfer chamber 13 (arrow A of FIG. 8). In the alignment module 40, as described above, the direction of the notch N formed at the peripheral portion of the wafer W and the center O of the wafer W are aligned. In this case, since the direction of the notch N is previously set to be zero degrees, the notch N is made to face the loading/unloading port 41a formed at the container 41. That is, as shown in FIG. 8, the notch N of the wafer W is set at a position on the reference line P to face the loading/unloading port 41a of the container 41.

Subsequently, the wafer W is unloaded from the alignment module 40 by the transfer arm unit 90. The unloaded wafer W is transferred to the load-lock chamber 12a (arrow B of FIG. 8). After the load-lock chamber 12a is vacuum-evacuated, the wafer W is unloaded from the load-lock chamber 12a by the transfer arm unit 50 in the vacuum transfer chamber 11. Then, the wafer W is loaded into the plasma processing module 20a (arrow C of FIG. 8) and, for example, a nitriding process is performed on the wafer W by using a plasma.

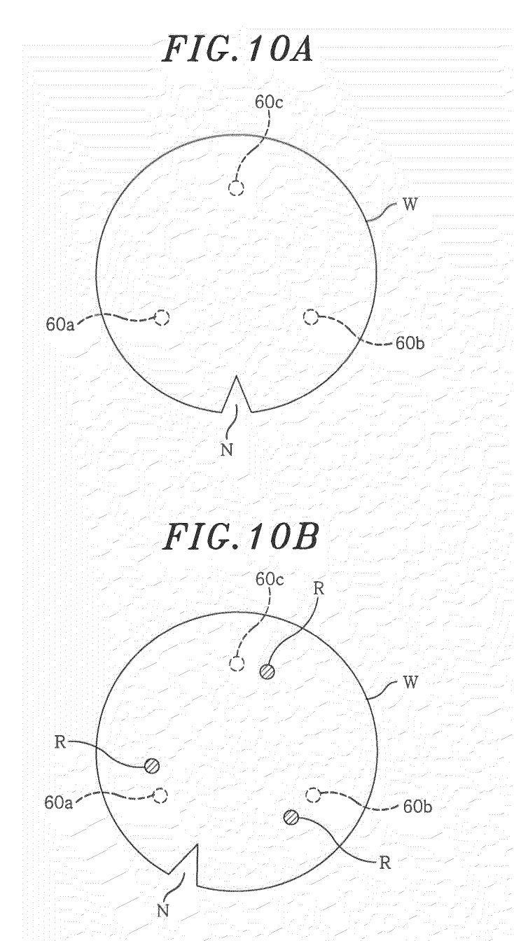

The wafer W that has been subjected to the nitriding process is loaded into the heat treatment module 30a by the transfer arm unit 50 in the vacuum transfer chamber 11 (arrow D of FIG. 8). Left and right fingers of the arm 52a are designed to extend in an outside region of the three supporting pins 60a, 60b and 60c provided in the mounting table 38 such that the arm 52a and the supporting pins 60a, 60b and 60c do not overlap each other in the plan view. Accordingly, when the arm 52a is moved down, the wafer W is delivered to the supporting pins 60a, 60b and 60c without interference between the arm 52a and the supporting pins 60a, 60b and 60c. A relationship between the positions of the supporting pins 60a, 60b and 60c and the direction of the notch N is represented in FIG. 10A.

After the arm 52a is withdrawn from the processing chamber 31, the processing chamber 31 is maintained at a pressure of about 133 Pa (1 Torr) to form a vacuum atmosphere therein. Then, the wafer W is heated to a temperature of about 10000 by radiant heat from the lamp 34 while the wafer W is rotated. Further, a gaseous mixture of N₂ gas and O₂ gas is supplied through the gas supply port 69 such that an annealing process is performed on the wafer W. The annealed wafer W is loaded into the load-lock chamber 12b by the transfer arm unit 50 (arrow E of FIG. 8). After the load-lock chamber 12b is maintained at an atmospheric pressure, the wafer W is returned to the original FOUP 9 by the transfer arm unit 90 in the atmospheric transfer chamber 13 (arrow F of FIG. 8).

The above-described operation is performed on each of wafers W of, e.g., one lot contained in the FOUP 9 and a series of processes is completed. The wafers W are transferred to another semiconductor manufacturing apparatus and are subjected to specific processes therein.

Then, the wafers W of the corresponding lot are loaded again into the semiconductor manufacturing apparatus 10. Also in this case, an operator sets a process recipe on the recipe setting screen 82 and inputs an alignment angle (excluding zero degrees) of the wafer W, i.e., an angle between a line passing through the center and notch of the aligned wafer W and the reference line P, e.g., 30 degrees, in the supplementary information section 84.

Thereafter, as in the above-described method, the wafer W is unloaded from the FOUP 9 mounted on the loading port 15a by the transfer arm unit 90 and is transferred to the alignment module 40 through the atmospheric transfer chamber 13. In the alignment module 40, as described above, the direction of the notch N formed on the peripheral portion of the wafer W and the center O of the wafer W are aligned (arrow A of FIG. 9). An angle of the notch of the wafer W has been determined in the supplementary information section 84. Accordingly, for example, as shown in FIG. 9, the wafer W is rotated clockwise by 30 degrees from the reference line P based on the determined angle of the notch. As a result, the notch N of the wafer W is arranged at a position deviated from the reference line P.

Then, the wafer W is loaded into the heat treatment module 30a from the alignment module 40 through the atmospheric transfer chamber 13, the load-lock chamber 12a and the vacuum transfer chamber 11 (arrows B and C of FIG. 9). In the heat treatment module 30a, as described above, the wafer W is loaded on the supporting pins 60a, 60b and 60c. As shown in FIG. 10B, the supporting pins 60a, 60b and 60c come in contact with portions of the wafer W different from portions R of the wafer W which are in contact with the supporting pins 60a, 60b and 60c in a first annealing process. In this state, the wafer W is supported from the bottom and a second annealing process is performed on the wafer W. For example, the second annealing process has the same process conditions as those of the first annealing process. The annealed wafer W is loaded into the load-lock chamber 12b by the transfer arm unit 50 (arrow D of FIG. 9), and is returned to the original FOUP 9 through the atmospheric transfer chamber 13 (arrow E of FIG. 9).

In accordance with the above-described embodiment of the present invention, the following effects can be achieved. A multi-chamber system includes processing chambers for plasma CVD, plasma etching, thermal CVD and the like, and such processes are performed on the wafer W while the wafer W is transferred in a predetermined direction. Accordingly, in the alignment module 40, the direction of the wafer W is required to be aligned in a predetermined direction. In this embodiment, the direction of the wafer W can be set as desired on the recipe setting screen (recipe setting interface) 82. Consequently, in a recipe in which only annealing is performed on the wafer W, portions of the wafer W supported by the supporting pins may differ in first and second annealing processes performed in the same heat treatment module 30a. Accordingly, stress due to a difference in temperatures of the portions supported by the supporting pins and the other portions can be prevented from being repeatedly applied to the same portions of the wafer W. Thus, wafer slip can be prevented or minimized, thereby preventing a reduction in production yield.

Further, the wafer W that has been subjected to a first annealing process and unloaded from the semiconductor manufacturing apparatus 10 will be subjected to a specific process according to the type of desired semiconductor devices. In this case, however, a second annealing process may be performed without performing the specific process. In order to evaluate the slip generated in the first annealing process, an annealing process may be performed on some wafers W in the lot that has undergone a first process for an accelerated test. In this case, the present invention can be applied. Further, the same (heat treatment) module means the same type of (heat treatment) modules, and does not necessarily mean the same (heat treatment) module itself. Accordingly, a case where a first annealing process is performed in the heat treatment module 30a and a second annealing process is performed in the heat treatment module 30b also corresponds to a case when the annealing processes are performed in the same heat treatment module, and the same effects can be obtained in both cases. Further, for example, after a plasma process and a first annealing process are sequentially performed on a wafer in a plasma processing module 20a and a heat treatment module 30a of a first semiconductor manufacturing apparatus, a second annealing process may be performed on the wafer in a heat treatment module 30a of a second semiconductor manufacturing apparatus.

Further, although the notch N is formed at the peripheral portion of the wafer W to determine the crystal direction and the direction of the notch N is set to align the direction of the wafer W in the above embodiment, an orientation flat may be formed instead of the notch N.

Further, the present invention may be also applied to a case where the heat treatment is performed twice in the same heat treatment module 30a in the semiconductor manufacturing apparatus 10 without being unloaded from the semiconductor manufacturing apparatus 10. For example, an annealing process may be performed as a pre-treatment and a post-treatment of the plasma process. That is, a first annealing process, a plasma process and a second annealing process may be performed in order. In this case, a wafer is transferred to the alignment module 40 before the second annealing process, and an alignment is performed such that the wafer is arranged in a direction different from a direction set before the first annealing process. In this case, preferably, the directions of the wafer in first and second alignments are set respectively on, e.g., the recipe setting screen 82.

Further, the present invention may be applied to a batch-type vertical heat treatment apparatus. For example, in the vertical heat treatment apparatus, the wafer is supported at three positions in a wafer boat, and loaded and processed in a tube.

Meanwhile, the direction of the wafer in the wafer carrier may not be changed depending on the type of the previous process. In this state, when the heat treatment is performed twice on the wafer by using the same vertical heat treatment apparatus, the above-mentioned problem occurs. Thus, an alignment mechanism may be provided in the vertical heat treatment apparatus and the recipe setting screen 82 may be provided as described above.

Further, although the loading ports 15a, 15b and 15c are connected to the vacuum transfer chamber 11 via the atmospheric transfer chamber 13 and the load-lock chambers 12a and 12b in the above embodiment, the present invention is not limited thereto. As an example, a vacuum-evacuable chamber may be connected directly to the vacuum transfer chamber 11 and the FOUP (carrier) may be loaded into the vacuum-evacuable chamber.

Further, although the alignment module 40 is provided on the side of the atmospheric transfer chamber 13 in the above embodiment, it is not limited thereto. For example, the alignment module 40 may be arranged at one position in a transfer path of the wafer W between the loading ports 15a, 15b and 15c and the heat treatment modules 30a and 30b, e.g., on the side of the vacuum transfer chamber 11.

While the invention has been shown and described with respect to the embodiments, it will be understood by those skilled in the art that various changes and modification may be made without departing from the scope of the invention as defined in the following claims.

What is claimed is:

1. A substrate treatment apparatus comprising:
a heat treatment module for performing heat treatment on a semiconductor wafer locally supported from a rear surface thereof by a supporting member provided in the heat treatment module;
a recipe setting unit configured to set process conditions of a process recipe of the semiconductor wafer and a direction of the semiconductor wafer by associating the conditions and the direction with each other;
an alignment module connected to the recipe setting unit to align the semiconductor wafer in the direction set by the recipe setting unit;
a loading port on which a carrier accommodating semiconductor wafers is loaded; and
a transfer unit for transferring a semiconductor wafer unloaded from the carrier loaded on the loading port to the alignment module,
wherein the transfer unit unloads the semiconductor wafer from the alignment module to transfer the semiconductor wafer to the heat treatment module.

2. The substrate treatment apparatus of claim 1, wherein the recipe setting unit has a recipe setting screen serving as an input unit through which the process conditions such as a transfer path of the wafer are set and a display unit on which setting contents are displayed.

3. The substrate treatment apparatus of claim 2, wherein the recipe setting screen includes a supplementary information section allowing input and display of supplementary information of the process recipe in addition to the process conditions, and the direction of the semiconductor wafer can be inputted through the supplementary information section.

4. The substrate treatment apparatus of claim 1, wherein the loading port is connected to a transfer chamber, and the transfer chamber is connected to the heat treatment module and a plasma processing module.

5. A substrate treatment method comprising the steps of:
(a) unloading a semiconductor wafer from a carrier loaded on a loading port and transferring the semiconductor wafer to an alignment module;
(b) aligning a direction of the semiconductor wafer at a first angle in the alignment module;
(c) loading the semiconductor wafer into the heat treatment module and performing heat treatment on the semiconductor wafer locally supported from a rear surface thereof by supporting members;
(d) aligning the direction of the semiconductor wafer at a second angle different from the first angle in the alignment module; and
(e) loading the semiconductor wafer into the same module as the heat treatment module and performing heat treatment on the semiconductor wafer locally supported from a rear surface thereof by supporting members.

6. The substrate treatment method of claim 5, wherein the semiconductor wafer is transferred from the alignment module to the heat treatment module through a transfer chamber, and the method further comprises performing a plasma process on the semiconductor wafer in a plasma processing module connected to the transfer chamber between the steps (b) and (d).

7. The substrate treatment method of claim 5, further comprising between the steps (c) and (d):
(c1) unloading the semiconductor wafer from the loading port; and
(c2) loading the semiconductor wafer accommodated in the carrier on the loading port again.

8. The substrate treatment method of claim 7, further comprising setting in advance the direction of the semiconductor wafer to be aligned by the alignment module by using a recipe setting unit between the steps (c1) and (c2).

9. A storage medium storing a program which is executed by a controller controlling a substrate treatment apparatus, including an alignment module for performing an alignment on a semiconductor wafer and a heat treatment module for performing heat treatment on the aligned semiconductor wafer, to perform a substrate treatment method including the steps of:
(a) unloading a semiconductor wafer from a carrier loaded on a loading port and transferring the semiconductor wafer to an alignment module;
(b) aligning a direction of the semiconductor wafer at a first angle in the alignment module;
(c) loading the semiconductor wafer into the heat treatment module and performing heat treatment on the semiconductor wafer locally supported from a rear surface thereof by supporting members;
(d) aligning the direction of the semiconductor wafer at a second angle different from the first angle in the alignment module; and
(e) loading the semiconductor wafer into the same module as the heat treatment module and performing heat treatment on the semiconductor wafer locally supported from a rear surface thereof by supporting members.
